(19) United States
(12) Patent Application Publication
(10) Pub. No.: US 2026/0052993 A1
(43) Pub. Date: Feb. 19, 2026

(54) SEMICONDUCTOR MODULE AND SEMICONDUCTOR DEVICE

(71) Applicant: ROHM CO., LTD., Kyoto (JP)

(72) Inventor: Shun FUKUSHIMA, Kyoto (JP)

(21) Appl. No.: 19/297,077

(22) Filed: Aug. 12, 2025

(30) Foreign Application Priority Data
Aug. 19, 2024 (JP) 2024-137642

(51) Int. Cl. H01L 23/58; H01L 23/31; H01L 23/482; H01L 23/495

(52) U.S. Cl. CPC H01L 23/58; H01L 23/3107; H01L 23/482; H01L 23/49562

(57) ABSTRACT

A semiconductor module includes: a substrate; and a semiconductor device that is located on one side of the substrate in a first direction and is conductively bonded to the substrate, wherein the semiconductor device includes: a first terminal, a second terminal, and a third terminal; a semiconductor element that is located on one side of the first terminal, the second terminal, and the third terminal in the first direction; and a sealing resin that covers the semiconductor element, wherein the semiconductor element includes a first circuit and a second circuit that are connected in series with each other, wherein the first circuit is electrically connected to the first terminal and the third terminal, wherein the second circuit is electrically connected to the second terminal and the third terminal, wherein the sealing resin has a bottom surface facing the substrate.

### CROSS REFERENCE TO RELATED APPLICATION

The present invention claims priority under 35 U.S.C. § 119 to Japanese Patent Application No. 2024-137642, filed on Aug. 19, 2024, the entire contents of which is incorporated herein by reference.

### TECHNICAL FIELD

The present disclosure relates to a semiconductor circuit and a semiconductor device including the semiconductor circuit.

### BACKGROUND

An example of a power supply circuit for a step-down DC/DC converter is disclosed in the related art. The power supply circuit includes two transistors. In the power supply circuit, the two transistors form a half-bridge circuit. A power supply voltage input to the power supply circuit is stepped down to a predetermined voltage by an inductor and an output capacitor, which are driven by each of the two transistors and connected to an output side of the half-bridge circuit.

In the power supply circuit disclosed in the related art, a conductive path connecting to an input side of the half-bridge circuit has a parasitic inductance. Therefore, when the power supply voltage input to the half-bridge circuit becomes higher, a surge voltage is generated in the conductive path. In a case where the surge voltage becomes too large, the two transistors forming the half-bridge circuit may be damaged. Here, it is possible to reduce the surge voltage by setting on/off transition time of each of the two transistors to be longer. However, there is a concern that this approach will result in a greater power loss due to the operation of the two transistors.

### BRIEF DESCRIPTION OF DRAWINGS

The accompanying drawings, which are incorporated in and constitute a part of the specification, illustrate embodiments of the present disclosure.

FIG. 1 is a plan view of a semiconductor module according to a first embodiment of the present disclosure.

FIG. 2 is a plan view corresponding to FIG. 1, with a sealing resin shown in a transparent manner.

FIG. 3 is a plan view corresponding to FIG. 2, with a semiconductor element further shown in a transparent manner.

FIG. 4 is a bottom view of a semiconductor device included in the semiconductor module shown in FIG. 1.

FIG. 5 is a front view of the semiconductor device included in the semiconductor module shown in FIG. 1.

FIG. 6 is a rear view of the semiconductor device included in the semiconductor module shown in FIG. 1.

FIG. 7 is a right side view of the semiconductor device included in the semiconductor module shown in FIG. 1.

FIG. 8 is a left side view of the semiconductor device included in the semiconductor module shown in FIG. 1.

FIG. 9 is a cross-sectional view taken along line IX-IX in FIG. 2.

FIG. 10 is a cross-sectional view taken along line X-X in FIG. 2.

FIG. 11 is a cross-sectional view taken along line XI-XI in FIG. 2.

FIG. 12 is a cross-sectional view taken along line XII-XII in FIG. 2.

FIG. 13 is a circuit diagram of a step-down DC/DC converter including the semiconductor module shown in FIG. 1 as a component.

FIG. 14 is a plan view of a semiconductor module according to a second embodiment of the present disclosure, with a sealing resin shown in a transparent manner.

FIG. 15 is a plan view corresponding to FIG. 14, with a semiconductor element further shown in a transparent manner.

FIG. 16 is a bottom view of a semiconductor device included in the semiconductor module shown in FIG. 14.

FIG. 17 is a cross-sectional view taken along line XVII-XVII in FIG. 14.

FIG. 18 is a cross-sectional view taken along line XVIII-XVIII in FIG. 14.

FIG. 19 is a plan view of a semiconductor module according to a third embodiment of the present disclosure, with a sealing resin shown in a transparent manner.

FIG. 20 is a plan view corresponding to FIG. 19, with a semiconductor element further shown in a transparent manner.

FIG. 21 is a bottom view of a semiconductor device included in the semiconductor module shown in FIG. 19.

FIG. 22 is a cross-sectional view taken along line XXII-XXII in FIG. 19.

FIG. 23 is a plan view of a semiconductor module according to a fourth embodiment of the present disclosure, with a sealing resin shown in a transparent manner.

FIG. 24 is a plan view corresponding to FIG. 23, with a semiconductor element further shown in a transparent manner.

FIG. 25 is a bottom view of a semiconductor device included in the semiconductor module shown in FIG. 23.

FIG. 26 is a cross-sectional view taken along line XXVI-XXVI in FIG. 23.

FIG. 27 is a cross-sectional view taken along line XXVII-XXVII in FIG. 23.

FIG. 28 is a plan view of a semiconductor device according to a fifth embodiment of the present disclosure, with a sealing resin shown in a transparent manner.

FIG. 29 is a bottom view of the semiconductor device shown in FIG. 28.

FIG. 30 is a bottom view of a semiconductor element included in the semiconductor device shown in FIG. 28.

FIG. 31 is a partially enlarged cross-sectional view of the semiconductor device shown in FIG. 28, showing a plurality of second electrodes of a semiconductor element and their vicinity.

FIG. 32 is a partially enlarged cross-sectional view of the semiconductor device shown in FIG. 28, showing a plurality of third electrodes of a semiconductor element and their vicinity.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Details of the present disclosure will be described with reference to the accompanying drawings.

### First Embodiment

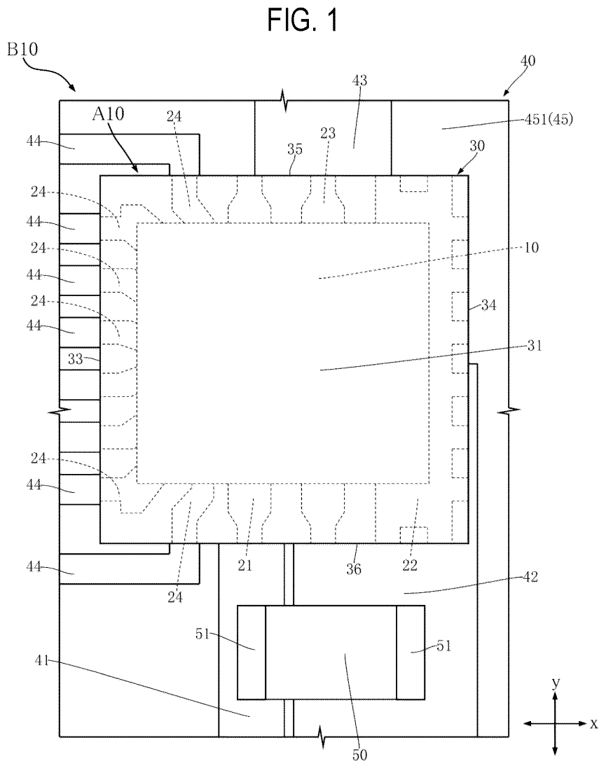

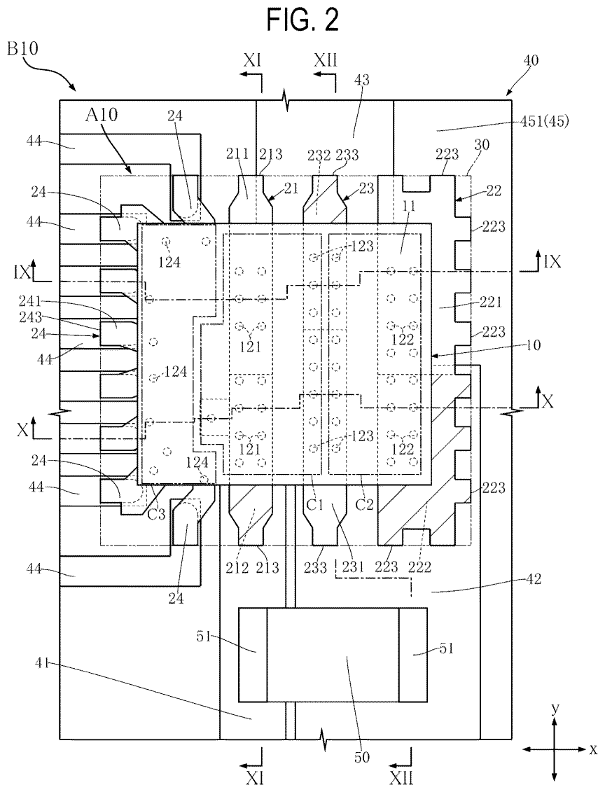

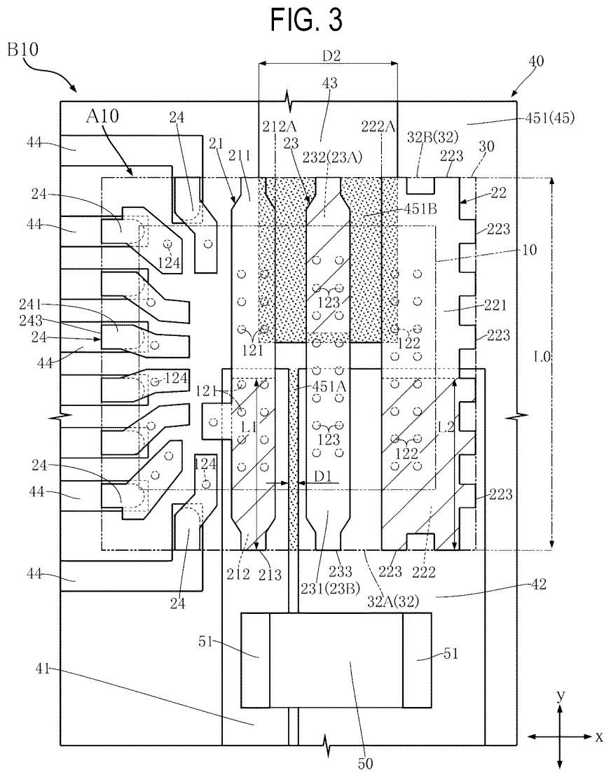

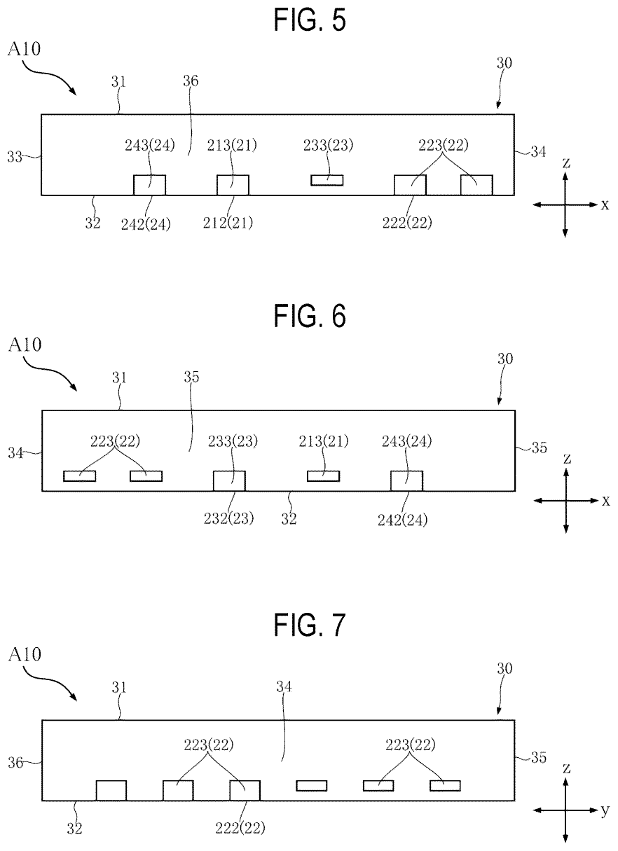

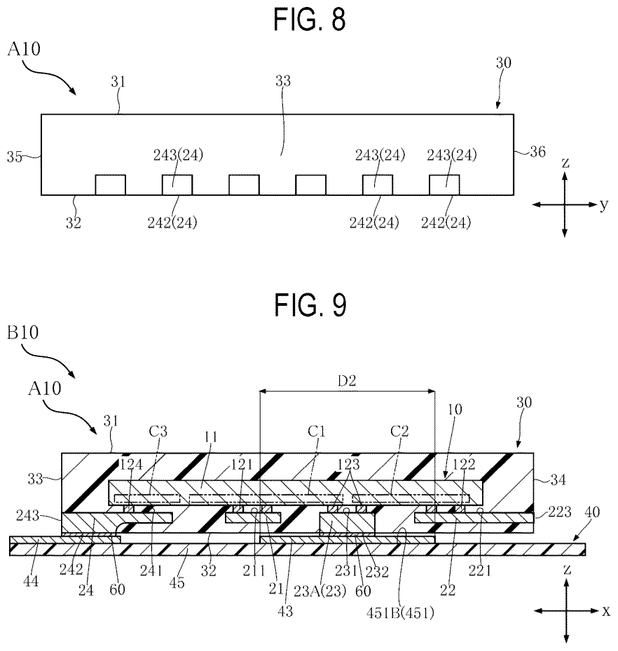

A semiconductor module B10 according to a first embodiment of the present disclosure will be described with reference to FIG. 1 to FIG. 12. The semiconductor module B10 constitutes, for example, a part of a circuit of a DC/DC converter. The semiconductor module B10 includes a semiconductor device A10, a substrate 40, and an input capacitor 50. The semiconductor device A10 is surface-mounted on the substrate 40. Here, for ease of understanding, FIG. 2 shows a sealing resin 30 in a transparent manner. In FIG. 2, the transparent sealing resin 30 is shown by an imaginary line (two-dot chain line). For ease of understanding, FIG. 3 further shows a semiconductor element 10 in a transparent manner in comparison with FIG. 2. In FIG. 3, the transparent sealing resin 30 and the transparent semiconductor element 10 are each shown by an imaginary line.

In the description of the semiconductor module B10, for the sake of convenience, a normal direction to the bottom surface 32 (details thereof will be described later) of the sealing resin 30 is called a “first direction z.” A direction perpendicular to the first direction z is called a “second direction x.” A direction perpendicular to both of the first direction z and the second direction x is called a “third direction y.”

First, the semiconductor device A10 included in the semiconductor module B10 will be described. The semiconductor device A10 has a rectangular shape when viewed in the first direction z. The semiconductor device A10 includes a semiconductor element 10, a first terminal 21, a second terminal 22, a third terminal 23, a plurality of fourth terminals 24, and a sealing resin 30.

As shown in FIG. 9 to FIG. 12, the sealing resin 30 covers the semiconductor element 10. Further, the sealing resin 30 covers a portion of each of the first terminal 21, the second terminal 22, and the third terminal 23, and a portion of each of the plurality of fourth terminals 24. The sealing resin 30 has electrical insulation properties. The sealing resin 30 is made of a material containing, for example, black epoxy resin.

As shown in FIG. 1 and FIGS. 4 to FIG. 8, the sealing resin 30 has a top surface 31, a bottom surface 32, a first side surface 33, a second side surface 34, a third side surface 35, and a fourth side surface 36. The top surface 31 faces one side in the first direction z. The bottom surface 32 faces the opposite side of the top surface 31 in the first direction z. In the semiconductor module B10, the bottom surface 32 faces the substrate 40. The first side surface 33 faces one side in the second direction x. The second side surface 34 faces the opposite side of the first side surface 33 in the second direction x. The third side surface 35 faces one side in the third direction y. The fourth side surface 36 faces the opposite side of the third side surface 35 in the third direction y. Each of the first side surface 33, the second side surface 34, the third side surface 35, and the fourth side surface 36 is connected to the top surface 31 and the bottom surface 32.

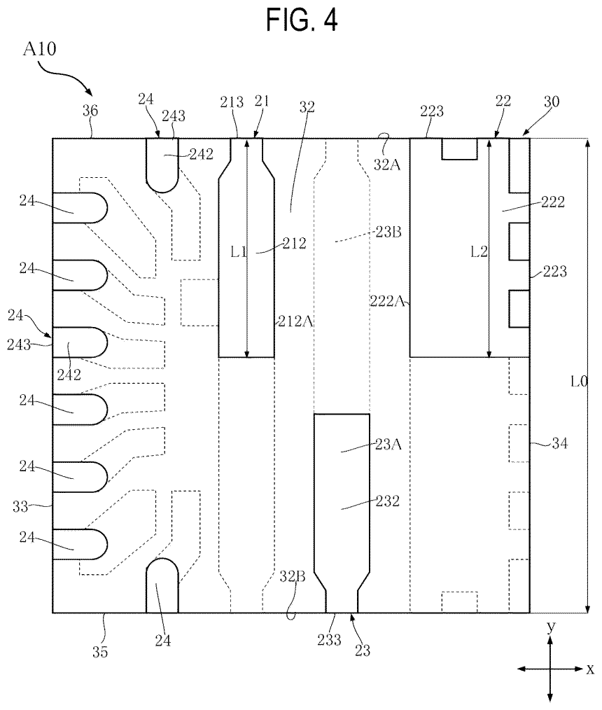

As shown in FIG. 4, the bottom surface 32 includes a third edge 32A and a fourth edge 32B. Each of the third edge 32A and the fourth edge 32B extends in the second direction x. The third edge 32A and the fourth edge 32B are separated from each other in the third direction y.

As shown in FIG. 9 to FIG. 12, the first terminal 21, the second terminal 22, the third terminal 23, and the plurality of fourth terminals 24 include the semiconductor element 10 mounted thereon. Each of the first terminal 21, the second terminal 22, the third terminal 23, and the plurality of fourth terminals 24 constitutes a conductive path between the substrate 40 and the semiconductor element 10. The first terminal 21, the second terminal 22, the third terminal 23, and the plurality of fourth terminals 24 all contain copper (Cu). The first terminal 21, the second terminal 22, the third terminal 23, and the plurality of fourth terminals 24 are obtained from the same lead frame.

As shown in FIG. 3 and FIG. 4, the first terminal 21 is located on the opposite side of the second terminal 22 with respect to the third terminal 23 in the second direction x. The first terminal 21 extends in the third direction y. The first terminal 21 has a first connection surface 211, a first mounting surface 212, and two first end surfaces 213.

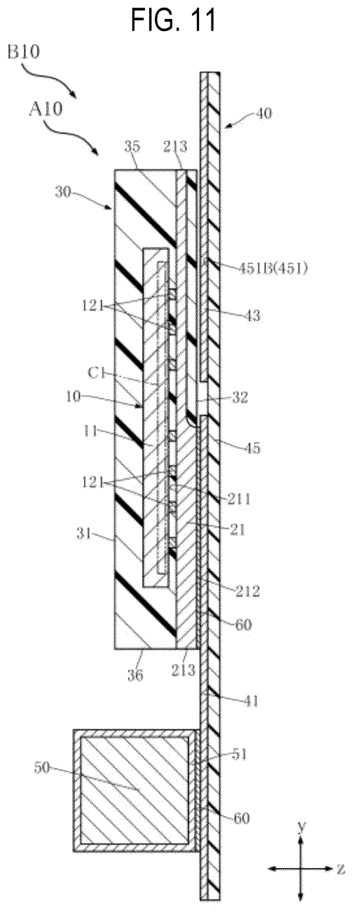

As shown in FIG. 9 to FIG. 11, the first connection surface 211 faces the same side as the top surface 31 of the sealing resin 30 in the first direction z. The first connection surface 211 faces the semiconductor element 10. The first connection surface 211 is covered with the sealing resin 30. The first mounting surface 212 faces the opposite side of the first connection surface 211 in the first direction z. As shown in FIG. 4, the first mounting surface 212 is exposed from the bottom surface 32 of the sealing resin 30. The first mounting surface 212 reaches the third edge 32A of the bottom surface 32 and is separated from the fourth edge 32B of the bottom surface 32. A dimension L1 of the first mounting surface 212 in the third direction y is 40% or more of a dimension L0 of the sealing resin 30 in the third direction y. As shown in FIG. 2 and FIG. 11, the two first end surfaces 213 face opposite sides to each other in the third direction y. One of the two first end surfaces 213 is exposed from the third side surface 35 of the sealing resin 30. The other of the two first end surfaces 213 is exposed from the fourth side surface 36 of the sealing resin 30.

As shown in FIG. 3 and FIG. 4, the second terminal 22 is located on the opposite side of the first terminal 21 with respect to the third terminal 23 in the second direction x. The second terminal 22 extends in the third direction y. The second terminal 22 has a second connection surface 221, a second mounting surface 222, and a plurality of second end surfaces 223.

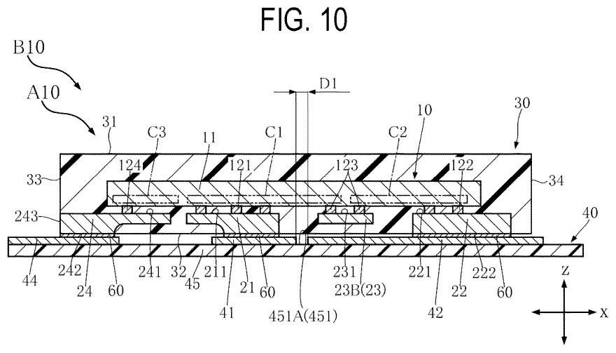

As shown in FIG. 9 and FIG. 10, the second connection surface 221 faces the same side as the top surface 31 of the sealing resin 30 in the first direction z. The second connection surface 221 faces the semiconductor element 10. The second connection surface 221 is covered with the sealing resin 30. The second mounting surface 222 faces the opposite side of the second connection surface 221 in the first direction z. As shown in FIG. 4, the second mounting surface 222 is exposed from the bottom surface 32 of the sealing resin 30. The second mounting surface 222 is separated from the first mounting surface 212 of the first terminal 21 in the second direction x. The second mounting surface 222 reaches the third edge 32A of the bottom surface 32 and is separated from the fourth edge 32B of the bottom surface 32. A dimension L2 of the second mounting surface 222 in the third direction y is 40% or more of the dimension L0 of the sealing resin 30 in the third direction y. As shown in FIG. 2 and FIG. 9, each of the plurality of second end surfaces 223 faces either the second direction x or the third direction y. Each of the plurality of second end surfaces 223 is exposed from either the second side surface 34, the third side surface 35, or the fourth side surface 36 of the sealing resin 30.

As shown in FIG. 3 and FIG. 4, the third terminal 23 is located between the first terminal 21 and the second terminal 22 in the second direction x. The third terminal 23 extends in the third direction y. The third terminal 23 has a third connection surface 231, a third mounting surface 232, and two third end surfaces 233.

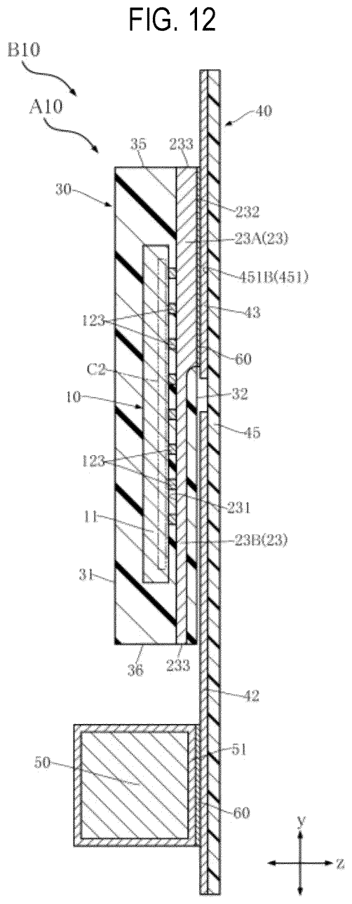

As shown in FIG. 9, FIG. 10, and FIG. 12, the third connection surface 231 and the first connection surface 211 face the same side as the top surface 31 of the sealing resin 30 in the first direction z. The third connection surface 231 faces the semiconductor element 10. The third connection surface 231 is covered with the sealing resin 30. The third mounting surface 232 faces the opposite side of the third connection surface 231 in the first direction z.

As shown in FIG. 4, the third mounting surface 232 is exposed from the bottom surface 32 of the sealing resin 30. Here, the first mounting surface 212 of the first terminal 21 includes a first edge 212A extending in the third direction y. The second mounting surface 222 of the second terminal 22 includes a second edge 222A extending in the third direction y. The second edge 222A is located adjacent to the first edge 212A in the second direction x. As shown in FIG. 3, the third mounting surface 232 is located between the first edge 212A and its extension line, and the second edge 222A and its extension line. The third mounting surface 232 is located on the opposite side of the side on which the third edge 32A of the bottom surface 32 is located, with respect to the first mounting surface 212 and the second mounting surface 222 in the third direction y. In the third direction y, a predetermined gap is provided between the third mounting surface 232 and each of the first mounting surface 212 and the second mounting surface 222. The third mounting surface 232 reaches the fourth edge 32B of the bottom surface 32.

As shown in FIG. 2 and FIG. 12, the two third end surfaces 233 face opposite sides to each other in the third direction y. One of the two third end surfaces 233 is exposed from the third side surface 35 of the sealing resin 30. The other of the two third end surfaces 233 is exposed from the fourth side surface 36 of the sealing resin 30.

As shown in FIG. 12, the third terminal 23 includes a first portion 23A and a second portion 23B. The first portion 23A includes the third mounting surface 232 and one of the two third end surfaces 233. The second portion 23B is connected to the first portion 23A and includes the other of the two third end surfaces 233. The second portion 23B is covered with the sealing resin 30. The third connection surface 231 is included in each of the first portion 23A and the second portion 23B. A dimension of the second portion 23B in the first direction z is smaller than a dimension of the first portion 23A in the first direction z.

As shown in FIG. 3 and FIG. 4, the plurality of fourth terminals 24 are located on the opposite side of the third terminal 23 with respect to the first terminal 21 in the second direction x. Each of the plurality of fourth terminals 24 has a fourth connection surface 241, a fourth mounting surface 242, and a fourth end surface 243.

As shown in FIG. 9 and FIG. 10, the fourth connection surface 241 faces the same side as the top surface 31 of the sealing resin 30 in the first direction z. The fourth connection surface 241 faces the semiconductor element 10. The fourth connection surface 241 is covered with the sealing resin 30. The fourth mounting surface 242 faces the opposite side of the fourth connection surface 241 in the first direction z. As shown in FIG. 4, the fourth mounting surface 242 is exposed from the bottom surface 32 of the sealing resin 30. The dimension L1 of the first mounting surface 212 of the first terminal 21 in the third direction y and the dimension L2 of the second mounting surface 222 of the second terminal 22 in the third direction y are larger than the dimensions of the fourth mounting surface 242 in the second direction x and the third direction y. As shown in FIG. 2, FIG. 9, and FIG. 10, the fourth end surface 243 faces either the second direction x or the third direction y. The fourth end surface 243 is exposed from either the first side surface 33, the third side surface 35, or the fourth side surface 36 of the sealing resin 30.

As shown in FIG. 9 to FIG. 11, the semiconductor element 10 is located on one side of the first terminal 21, the second terminal 22, the third terminal 23, and the plurality of fourth terminals 24 in the first direction z. The semiconductor element 10 includes a main body 11, a plurality of first electrodes 121, a plurality of second electrodes 122, a plurality of third electrodes 123, and a plurality of fourth electrodes 124.

The main body 11 includes a semiconductor substrate and a semiconductor layer laminated on the semiconductor substrate. A first circuit C1, a second circuit C2, and a third circuit C3 are formed in the semiconductor layer. The first circuit C1 and the second circuit C2 are connected in series with each other. Each of the first circuit C1 and the second circuit C2 includes a switching element. The switching element is, for example, an n-channel metal oxide semiconductor field effect transistor (MOSFET). In the present disclosure, each of the first circuit C1 and the second circuit C2 includes an n-channel MOSFET. In the main body 11, a half-bridge circuit is constituted by the first circuit C1 and the second circuit C2. The third circuit C3 is electrically connected to each of the first circuit C1 and the second circuit C2. The third circuit C3 controls each of the first circuit C1 and the second circuit C2.

As shown in FIG. 2, when viewed in the first direction z, the first mounting surface 212 of the first terminal 21 and the second mounting surface 222 of the second terminal 22 overlap the first circuit C1 and the second circuit C2, respectively. When viewed in the first direction z, the third mounting surface 232 of the third terminal 23 overlaps at least one selected from the group of the first circuit C1 and the second circuit C2.

Each of the plurality of first electrodes 121 is electrically connected to the first circuit C1. As shown in FIG. 2, when viewed in the first direction z, each of the plurality of first electrodes 121 overlaps the first circuit C1. As shown in FIG. 9 to FIG. 11, each of the plurality of first electrodes 121 is conductively bonded to the first connection surface 211 of the first terminal 21 via solder or the like.

Each of the plurality of second electrodes 122 is electrically connected to the second circuit C2. As shown in FIG. 2, when viewed in the first direction z, each of the plurality of second electrodes 122 overlaps the second circuit C2. As shown in FIG. 9 and FIG. 10, each of the plurality of second electrodes 122 is conductively bonded to the second connection surface 221 of the second terminal 22 via solder or the like.

Each of the plurality of third electrodes 123 is electrically connected to the first circuit C1 and the second circuit C2. As shown in FIG. 2, when viewed in the first direction z, each of the plurality of third electrodes 123 overlaps either the first circuit C1 or the second circuit C2. As shown in FIG. 9, FIG. 10, and FIG. 11, each of the plurality of third electrodes 123 is conductively bonded to the third connection surface 231 of the third terminal 23 via solder or the like. Further, each of the plurality of third electrodes 123 is conductively bonded to either the first portion 23A of the third terminal 23 or the second portion 23B of the third terminal 23.

Each of the plurality of fourth electrodes 124 is electrically connected to the third circuit C3. As shown in FIG. 2, when viewed in the first direction z, each of the plurality of fourth electrodes 124 overlaps the third circuit C3. As shown in FIG. 9 and FIG. 10, each of the plurality of fourth electrodes 124 is conductively bonded to the fourth connection surface 241 of any of the plurality of fourth terminals 24 via solder or the like.

Next, the substrate 40 and the input capacitor 50 included in the semiconductor module B10 will be described.

The substrate 40 is, for example, a printed wiring board (PWB). The substrate 40 includes a first conductive layer 41, a second conductive layer 42, a third conductive layer 43, a plurality of fourth conductive layers 44, and an insulating layer 45. Each of the first conductive layer 41, the second conductive layer 42, the third conductive layer 43, and the plurality of fourth conductive layers 44 includes copper. The insulating layer 45 is made of a material containing, for example, epoxy resin.

As shown in FIG. 9 to FIG. 12, the insulating layer 45 faces the semiconductor device A10. The insulating layer 45 has a mounting surface 451 facing the bottom surface 32 of the sealing resin 30.

As shown in FIG. 3 and FIGS. 9 to FIG. 12, the first conductive layer 41, the second conductive layer 42, the third conductive layer 43, and the plurality of fourth conductive layers 44 are mounted on the mounting surface 451 of the insulating layer 45. The first mounting surface 212 of the first terminal 21 is conductively bonded to the first conductive layer 41 via a bonding layer 60. The bonding layer 60 is, for example, solder. The second conductive layer 42 is located adjacent to the first conductive layer 41 in the second direction x. The second mounting surface 222 of the second terminal 22 is conductively bonded to the second conductive layer 42 via the bonding layer 60. The third conductive layer 43 is located on one side of the first conductive layer 41 and the second conductive layer 42 in the third direction y. The third mounting surface 232 of the third terminal 23 is conductively bonded to the third conductive layer 43 via the bonding layer 60. The plurality of fourth conductive layers 44 are located on one side of the first conductive layer 41 and the third conductive layer 43 in the second direction x. The fourth mounting surface 242 of each of the plurality of fourth terminals 24 is individually conductively bonded to the plurality of fourth conductive layers 44 via the bonding layer 60.

As shown in FIG. 3, FIG. 9, and FIG. 10, the mounting surface 451 of the insulating layer 45 includes a first region 451A and a second region 451B. When viewed in the first direction z, the entirety of the first region 451A and the second region 451B each overlaps the bottom surface 32 of the sealing resin 30. When viewed in the first direction z, the first region 451A is interposed between the first conductive layer 41 and the second conductive layer 42. When viewed in the first direction z, the second region 451B is located on the opposite side of the third edge 32A of the bottom surface 32 with respect to the first region 451A in the third direction y. When viewed in the first direction z, a dimension D2 of a portion of the third conductive layer 43 overlapping the second region 451B in the second direction x is greater than a minimum dimension D1 of the first region 451A in the second direction x.

As shown in FIG. 1 to FIG. 3, the input capacitor 50 is located on the opposite side of the first mounting surface 212 of the first terminal 21 and the second mounting surface 222 of the second terminal 22 with respect to the third edge 32A of the bottom surface 32 of the sealing resin 30 in the third direction y. The input capacitor 50 includes two electrodes 51. As shown in FIG. 11, one of the two electrodes 51 is conductively bonded to the first conductive layer 41 via the bonding layer 60. As shown in FIG. 12, the other of the two electrodes 51 is conductively bonded to the second conductive layer 42 via the bonding layer 60.

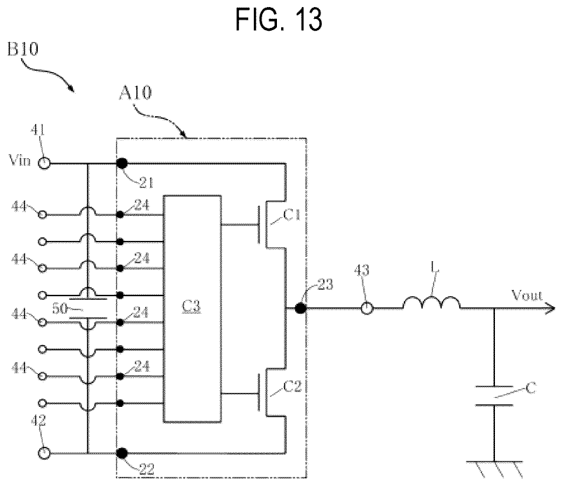

Next, a step-down DC/DC converter circuit including the semiconductor module B10 as a component will be described with reference to FIG. 13. The circuit includes the semiconductor module B10, an inductor L, and an output capacitor C.

The inductor L is electrically connected to the third conductive layer 43. Therefore, the inductor L is electrically connected to a source of the first circuit C1 and a drain of the second circuit C2 via the third conductive layer 43 and the third terminal 23.

The output capacitor C is electrically connected to the inductor L. More specifically, a positive electrode of the output capacitor C is electrically connected to the inductor L. A negative electrode of the output capacitor C is grounded to the outside. In this circuit, the inductor L and the output capacitor C constitute a low-pass filter.

Next, an operation of this circuit will be described. When an input voltage Vᵢₙ to be stepped down is applied to the first conductive layer 41, the first circuit C1 is driven by the third circuit C3. Here, the second conductive layer 42 is grounded corresponding to the input voltage Vᵢₙ. As a result, a pulsed input voltage Vᵢₙ is obtained in the third conductive layer 43. At this time, a gate voltage based on a pulse width modulation (PWM) control by the third circuit C3 is applied to the first circuit C1. In this case, the input capacitor 50 contributes to stabilizing a waveform of the pulsed input voltage Vᵢₙ. Next, the second circuit C2 is driven by the third circuit C3. As a result, the pulsed input voltage Vᵢₙ is smoothed by the inductor L and the output capacitor C and is converted into a stepped-down output voltage Vₒᵤₜ. The output voltage Vₒᵤₜ is output to the outside. Therefore, this circuit employs a synchronous rectification method.

Next, operation and effects of the semiconductor module B10 will be described.

The semiconductor module B10 includes the semiconductor device A10 and the substrate 40. The semiconductor device A10 includes the first terminal 21, the second terminal 22, the third terminal 23, the semiconductor element 10, and the sealing resin 30. The semiconductor element 10 includes the first circuit C1 and the second circuit C2. The substrate 40 includes the first conductive layer 41, the second conductive layer 42, the third conductive layer 43, and the insulating layer 45. The mounting surface 451 of the insulating layer 45 includes the first region 451A and the second region 451B. When viewed in the first direction z, the first region 451A is interposed between the first conductive layer 41 and the second conductive layer 42. When viewed in the first direction z, the second region 451B is located on the opposite side of the third edge 32A of the bottom surface 32 of the sealing resin 30 with respect to the first region 451A. When viewed in the first direction z, the dimension D2 of the portion of the third conductive layer 43 overlapping the second region 451B in the second direction x is greater than the minimum dimension D1 of the first region 451A in the first direction z. By adopting this configuration, a conductive path from the first conductive layer 41 to the second conductive layer 42 via the first terminal 21, the first circuit C1, the second circuit C2, and the second terminal 22 in this order is further shortened. Further, a distance between a current flowing through the conductive path in the first conductive layer 41 and a current flowing through the conductive path in the second conductive layer 42 becomes smaller. This further reduces a parasitic inductance caused by the conductive path in the semiconductor module B10. Therefore, according to this configuration, in the semiconductor module B10, it is possible to reduce the parasitic inductance without increasing a power loss associated with the operation of each of the first circuit C1 and the second circuit C2.

The semiconductor element 10 includes the first electrode 121, the second electrode 122, and the third electrode 123. The first electrode 121, the second electrode 122, and the third electrode 123 are individually conductively bonded to the first terminal 21, the second terminal 22, and the third terminal 23, respectively. By adopting this configuration, in the semiconductor device A10, the semiconductor element 10 is flip-chip connected to the first terminal 21, the second terminal 22, and the third terminal 23. This makes it possible to reduce the parasitic inductance in the semiconductor device A10.

The dimensions L1 and L2 of the first mounting surface 212 of the first terminal 21 and the second mounting surface 222 of the second terminal 22 in the third direction y are 40% or more of the dimension L0 of the sealing resin 30 in the third direction y. By adopting this configuration, more current can flow from each of the first conductive layer 41 and the second conductive layer 42 to the semiconductor device A10.

The semiconductor module B10 further includes the input capacitor 50 conductively bonded to the first conductive layer 41 and the second conductive layer 42. The input capacitor 50 is located on the opposite side of the first mounting surface 212 of the first terminal 21 and the second mounting surface 222 of the second terminal 22 with respect to the third edge 32A of the bottom surface 32 of the sealing resin 30 in the third direction y. By adopting this configuration, it becomes easier to optimize the conductive path of each of the first conductive layer 41 and the second conductive layer 42 between the input voltage side and the semiconductor device A10 in the circuit configuration of the DC/DC converter shown in FIG. 13.

### Second Embodiment

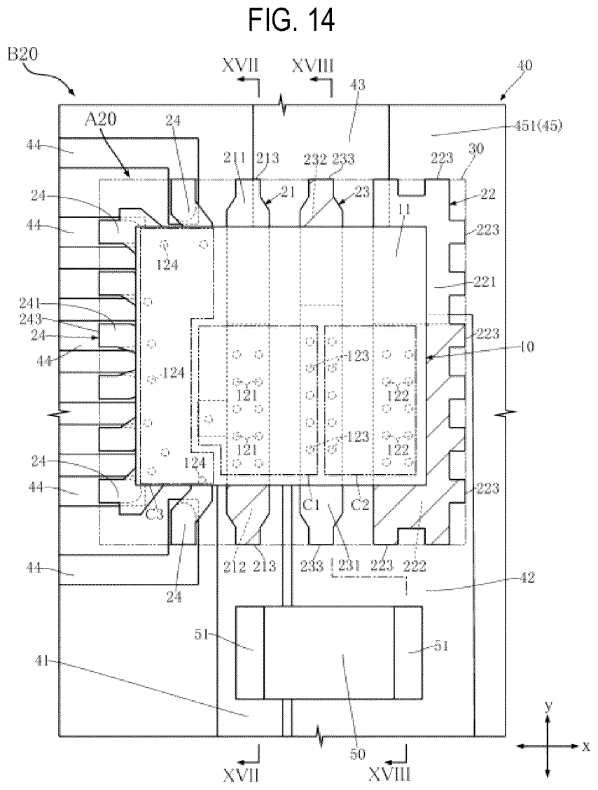

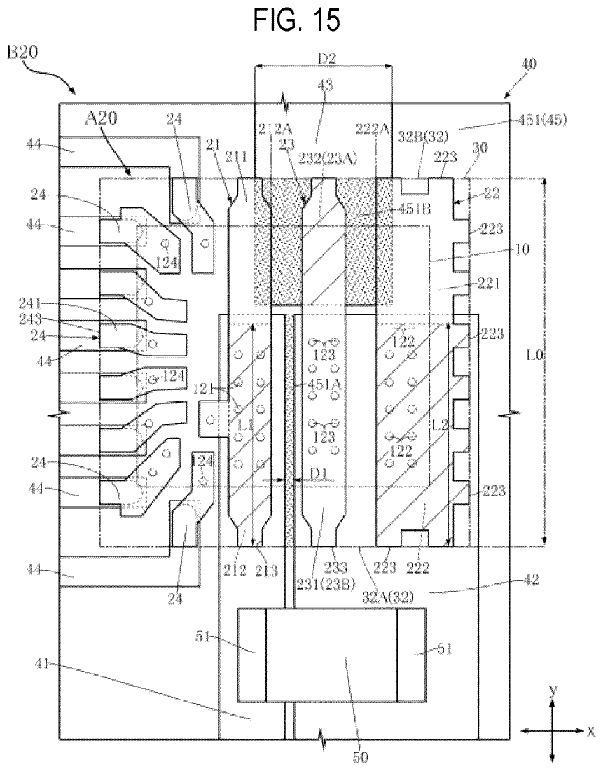

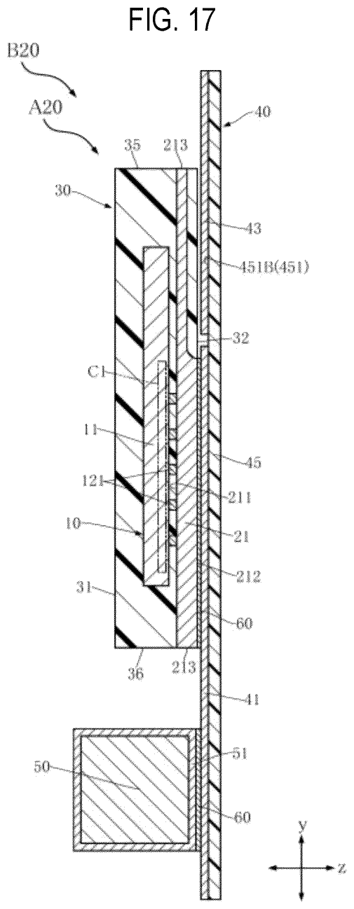

A semiconductor module B20 according to a second embodiment of the present disclosure will be described with reference to FIG. 14 to FIG. 18. In these figures, elements that are the same as or similar to those of the above-described semiconductor module B10 and semiconductor device A10 are denoted by the same reference numerals, and redundant descriptions thereof will be omitted. Here, for ease of understanding, FIG. 14 shows the sealing resin 30 in a transparent manner. In FIG. 14, the transparent sealing resin 30 is shown by an imaginary line. For ease of understanding, FIG. 15 further shows the semiconductor element 10 in a transparent manner in comparison with FIG. 14. In FIG. 15, the transparent sealing resin 30 and the semiconductor element 10 are each shown by imaginary lines.

The semiconductor module B20 includes a semiconductor device A20, a substrate 40, and an input capacitor 50. The semiconductor device A20 includes a semiconductor element 10, a first terminal 21, a second terminal 22, a third terminal 23, a plurality of fourth terminals 24, and a sealing resin 30. In the semiconductor module B20, configurations of the semiconductor element 10, the first terminal 21, the second terminal 22, and the third terminal 23 are different from those of the semiconductor module B10.

As shown in FIG. 14, when viewed in the first direction z, an area occupied by each of the first circuit C1 and the second circuit C2 in the main body 11 of the semiconductor element 10 is set to be smaller than that of the semiconductor module B10.

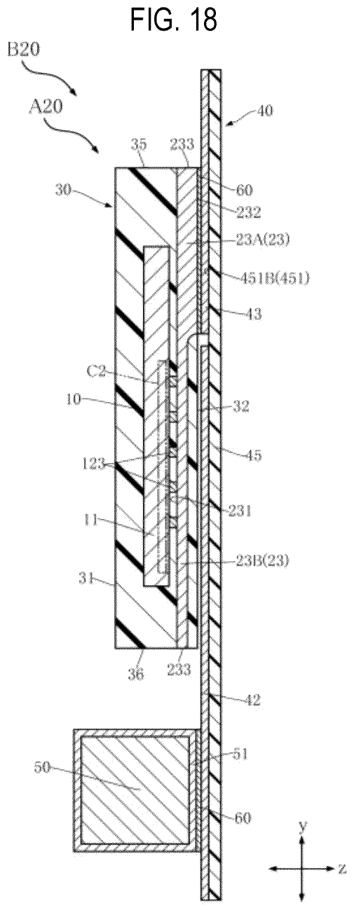

As shown in FIG. 15, when viewed in the first direction z, the third mounting surface 232 of the third terminal 23 is separated from each of the first circuit C1 and the second circuit C2 of the semiconductor element 10. As shown in FIG. 18, each of the plurality of third electrodes 123 of the semiconductor element 10 is conductively bonded to the third connection surface 231 of the second portion 23B of the third terminal 23.

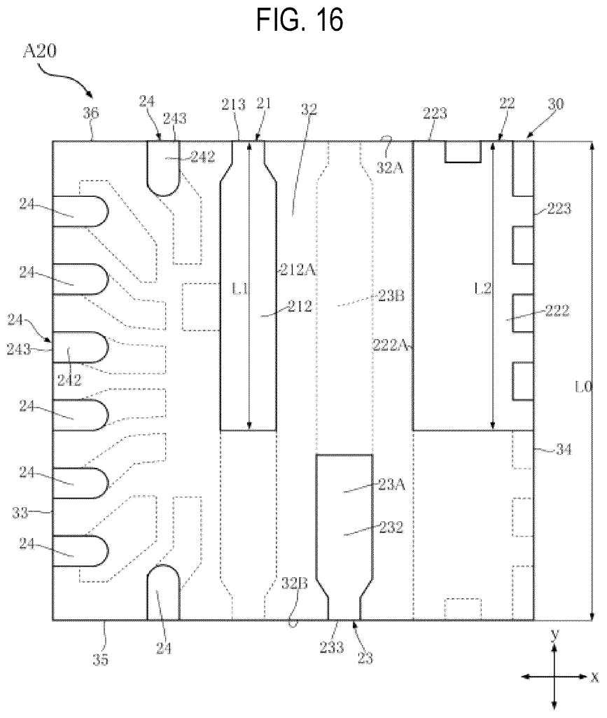

As shown in FIG. 15 and FIG. 16, the dimension L1 of the first mounting surface 212 of the first terminal 21 in the third direction y and the dimension L2 of the second mounting surface 222 of the second terminal 22 in the third direction y are each set to be larger than those in the configuration of the semiconductor module B10.

Next, operation and effects of the semiconductor module B20 will be described.

The semiconductor module B20 includes the semiconductor device A20 and the substrate 40. The semiconductor device A20 includes the first terminal 21, the second terminal 22, the third terminal 23, the semiconductor element 10, and the sealing resin 30. The semiconductor element 10 includes the first circuit C1 and the second circuit C2. The substrate 40 includes the first conductive layer 41, the second conductive layer 42, the third conductive layer 43, and the insulating layer 45. The mounting surface 451 of the insulating layer 45 includes the first region 451A and the second region 451B. When viewed in the first direction z, the first region 451A is interposed between the first conductive layer 41 and the second conductive layer 42. When viewed in the first direction z, the second region 451B is located on the opposite side of the third edge 32A of the bottom surface 32 of the sealing resin 30 with respect to the first region 451A. When viewed in the first direction z, the dimension D2 of the portion of the third conductive layer 43 overlapping the second region 451B in the second direction x is greater than the minimum dimension D1 of the first region 451A in the first direction z. Therefore, according to this configuration, even in the semiconductor module B20, it is possible to reduce the parasitic inductance without increasing the power loss associated with the operation of each of the first circuit C1 and the second circuit C2. Further, in the semiconductor module B20, by providing a configuration common to the semiconductor module B10, the same operation and effects as those of the semiconductor module B10 are achieved.

In the semiconductor module B20, when viewed in the first direction z, the third mounting surface 232 of the third terminal 23 is separated from each of the first circuit C1 and the second circuit C2 of the semiconductor element 10. By adopting this configuration, the conductive path from the first conductive layer 41 to the second conductive layer 42 via the first terminal 21, the first circuit C1, the second circuit C2, and the second terminal 22 in this order is further shortened. This makes it possible to more effectively reduce the parasitic inductance caused by the conductive path in the semiconductor module B20.

### Third Embodiment

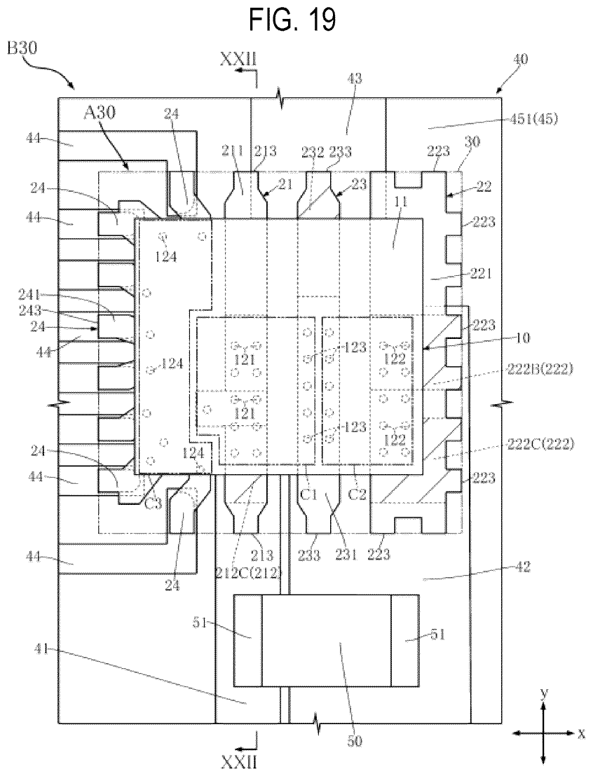

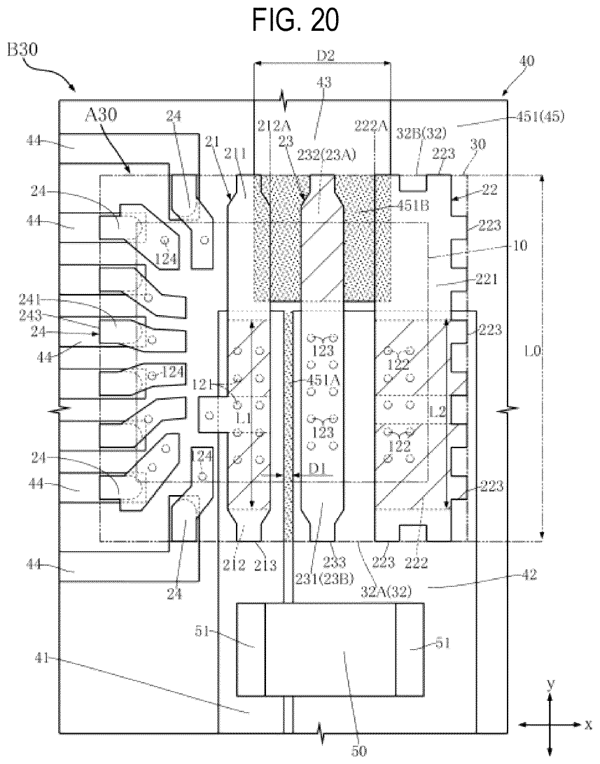

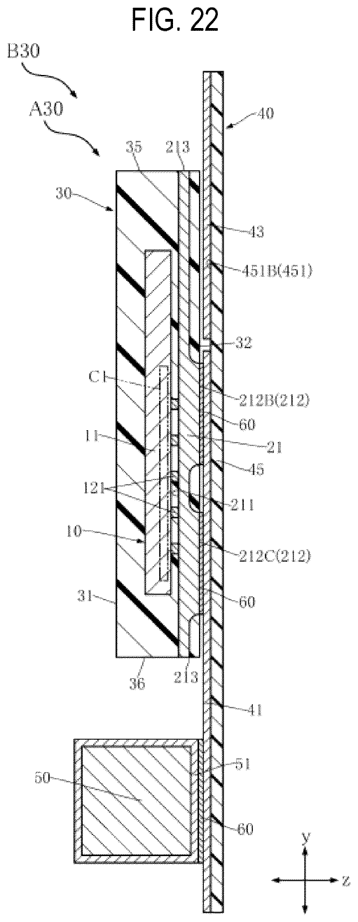

A semiconductor module B30 according to a third embodiment of the present disclosure will be described with reference to FIG. 19 to FIG. 22. In these figures, elements that are the same as or similar to those in the above-described semiconductor module B10 and the semiconductor device A10 are denoted by the same reference numerals, and redundant descriptions thereof will be omitted. Here, for ease of understanding, FIG. 19 shows the sealing resin 30 in a transparent manner. In FIG. 19, the transparent sealing resin 30 is shown by an imaginary line. For ease of understanding, FIG. 20 further shows the semiconductor element 10 in a transparent manner in comparison with FIG. 19. In FIG. 20, the transparent sealing resin 30 and the semiconductor element 10 are each shown by imaginary lines.

The semiconductor module B30 includes a semiconductor device A30, a substrate 40, and an input capacitor 50. The semiconductor device A30 includes a semiconductor element 10, a first terminal 21, a second terminal 22, a third terminal 23, a plurality of fourth terminals 24, and a sealing resin 30. In the semiconductor module B30, configurations of the first terminal 21 and the second terminal 22 are different from those of the above-described semiconductor module B20.

As shown in FIG. 20 to FIG. 22, the first mounting surface 212 of the first terminal 21 includes a first surface 212B and a second surface 212C that are spaced apart from each other in the third direction y. Each of the first surface 212B and the second surface 212C is spaced apart from the third edge 32A of the bottom surface 32 of the sealing resin 30. In the semiconductor module B30, the dimension L1 of the first mounting surface 212 in the third direction y corresponds to a distance from the end of the first surface 212B, which is closest to the fourth edge 32B of the bottom surface 32, to the end of the second surface 212C, which is closest to the third edge 32A of the bottom surface 32 in the third direction y.

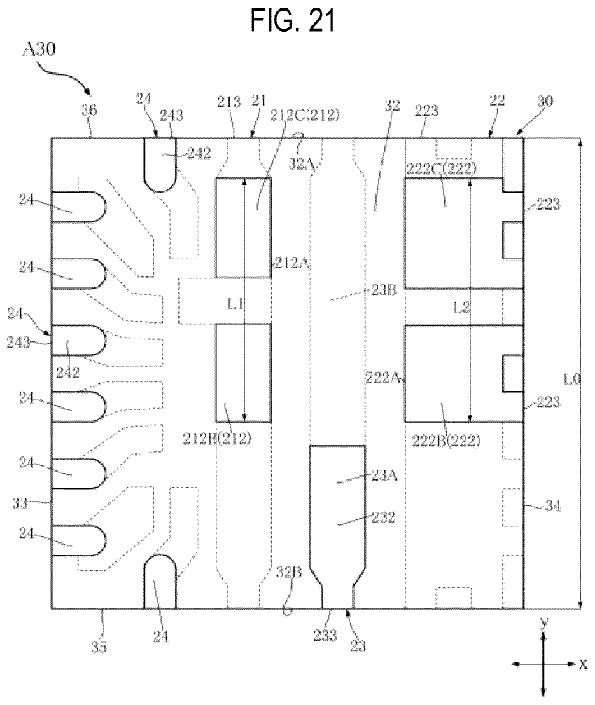

As shown in FIG. 20 and FIG. 21, the second mounting surface 222 of the second terminal 22 includes a third surface 222B and a fourth surface 222C that are spaced apart from each other in the third direction y. Each of the third surface 222B and the fourth surface 222C is spaced apart from the third edge 32A of the bottom surface 32 of the sealing resin 30. In the semiconductor module B30, the dimension L2 of the second mounting surface 222 in the third direction y corresponds to a distance from the end of the third surface 222B, which is closest to the fourth edge 32B of the bottom surface 32, to the end of the fourth surface 222C, which is closest to the third edge 32A of the bottom surface 32 in the third direction y.

Next, operation and effects of the semiconductor module B30 will be described.

The semiconductor module B30 includes the semiconductor device A30 and the substrate 40. The semiconductor device A30 includes the first terminal 21, the second terminal 22, the third terminal 23, the semiconductor element 10, and the sealing resin 30. The semiconductor element 10 includes the first circuit C1 and the second circuit C2. The substrate 40 includes the first conductive layer 41, the second conductive layer 42, the third conductive layer 43, and the insulating layer 45. The mounting surface 451 of the insulating layer 45 includes the first region 451A and the second region 451B. When viewed in the first direction z, the first region 451A is interposed between the first conductive layer 41 and the second conductive layer 42. When viewed in the first direction z, the second region 451B is located on the opposite side of the third edge 32A of the bottom surface 32 of the sealing resin 30 with respect to the first region 451A. When viewed in the first direction z, the dimension D2 of the portion of the third conductive layer 43 overlapping the second region 451B in the second direction x is greater than the minimum dimension D1 of the first region 451A in the first direction z. Therefore, according to this configuration, even in the semiconductor module B30, it is possible to reduce the parasitic inductance without increasing the power loss associated with the operation of each of the first circuit C1 and the second circuit C2. Further, in the semiconductor module B30, by providing a configuration common to the semiconductor module B10, the same operation and effects as those of the semiconductor module B10 are achieved.

In the semiconductor module B30, the first mounting surface 212 of the first terminal 21 includes the first surface 212B and the second surface 212C that are spaced apart from each other in the third direction y. By adopting this configuration, a portion of the first terminal 21 located between the first surface 212B and the second surface 212C in the third direction y is interposed in the sealing resin 30 from both sides in the first direction z. This more effectively prevents the first terminal 21 from falling off the bottom surface 32 of the sealing resin 30.

### Fourth Embodiment

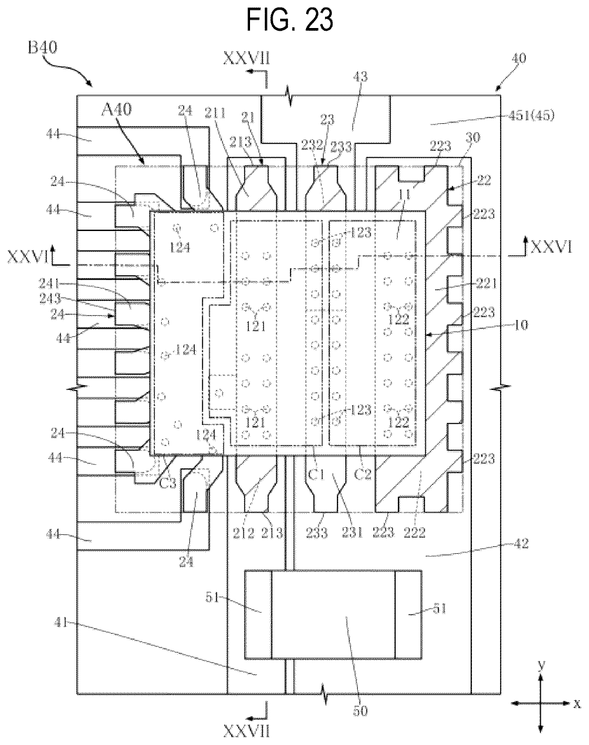

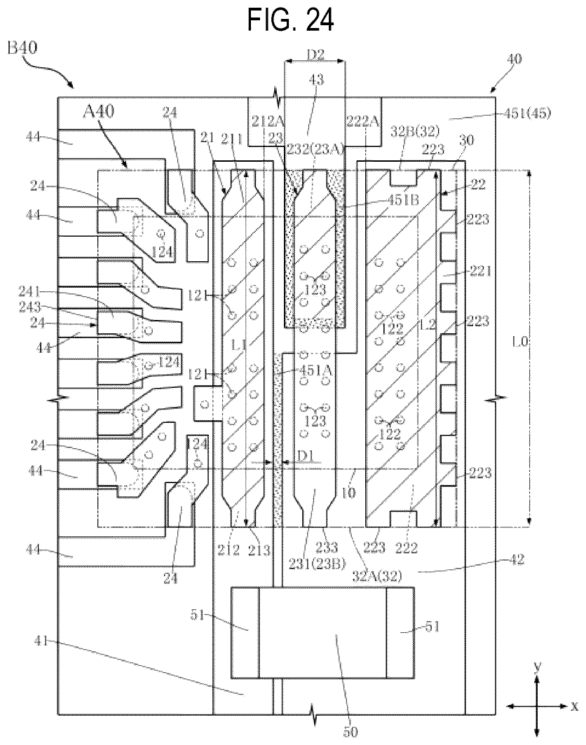

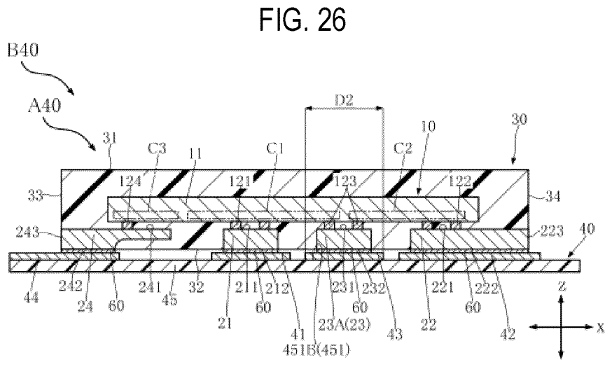

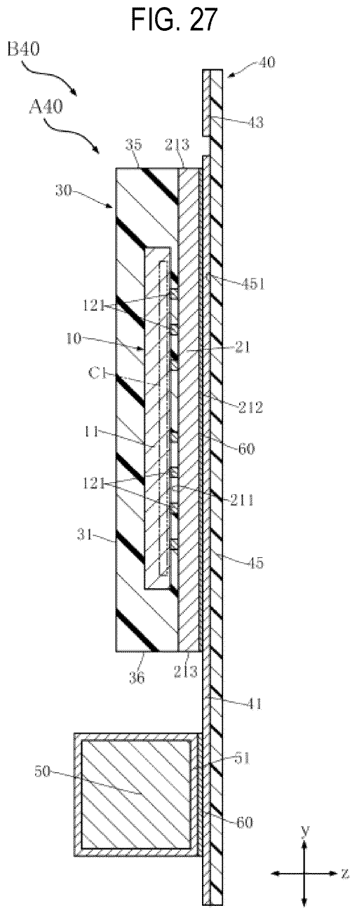

A semiconductor module B40 according to a fourth embodiment of the present disclosure will be described with reference to FIG. 23 to FIG. 27. In these figures, elements that are the same as or similar to those of the above-described semiconductor module B10 and semiconductor device A10 are denoted by the same reference numerals, and redundant descriptions thereof will be omitted. Here, for ease of understanding, FIG. 23 shows the sealing resin 30 in a transparent manner. In FIG. 23, the transparent sealing resin 30 is shown by an imaginary line. For ease of understanding, FIG. 24 further shows the semiconductor element 10 in a transparent manner in comparison with FIG. 23. In FIG. 24, the transparent sealing resin 30 and the semiconductor element 10 are each shown by imaginary lines.

The semiconductor module B40 includes a semiconductor device A40, a substrate 40, and an input capacitor 50. The semiconductor device A40 includes a semiconductor element 10, a first terminal 21, a second terminal 22, a third terminal 23, a plurality of fourth terminals 24, and a sealing resin 30. In the semiconductor module B40, configurations of the first terminal 21 and the second terminal 22 are different from those of the semiconductor module B10.

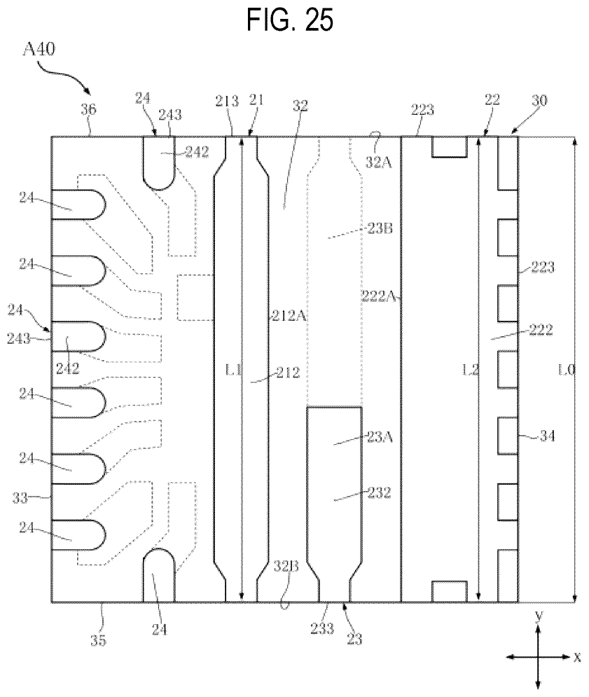

As shown in FIG. 24 and FIG. 25, the first mounting surface 212 of the first terminal 21 extends from the third edge 32A to the fourth edge 32B of the bottom surface 32 of the sealing resin 30. As a result, the dimension L1 of the first mounting surface 212 in the third direction y is equal to the dimension L0 of the sealing resin 30 in the third direction y.

As shown in FIG. 24 and FIG. 25, the second mounting surface 222 of the second terminal 22 extends from the third edge 32A to the fourth edge 32B of the bottom surface 32 of the sealing resin 30. As a result, the dimension L2 of the second mounting surface 222 in the third direction y is equal to the dimension L0 of the sealing resin 30 in the third direction y.

As shown in FIG. 23 to FIG. 27, when viewed in the first direction z, an area of a portion of the first conductive layer 41 that overlaps the sealing resin 30 is set to be larger than that of the semiconductor module B10. As shown in FIG. 23 to FIG. 26, when viewed in the first direction z, an area of a portion of the second conductive layer 42 that overlaps the sealing resin 30 is set to be larger than that of the semiconductor module B10. As shown in FIG. 24, the second region 451B of the mounting surface 451 of the insulating layer 45 is located between the first conductive layer 41 and the second conductive layer 42 in the second direction X.

Next, operation and effects of the semiconductor module B40 will be described.

The semiconductor module B40 includes the semiconductor device A40 and the substrate 40. The semiconductor device A40 includes the first terminal 21, the second terminal 22, the third terminal 23, the semiconductor element 10, and the sealing resin 30. The semiconductor element 10 includes the first circuit C1 and the second circuit C2. The substrate 40 includes the first conductive layer 41, the second conductive layer 42, the third conductive layer 43, and the insulating layer 45. The mounting surface 451 of the insulating layer 45 includes the first region 451A and the second region 451B. When viewed in the first direction z, the first region 451A is interposed between the first conductive layer 41 and the second conductive layer 42. When viewed in the first direction z, the second region 451B is located on the opposite side of the third edge 32A of the bottom surface 32 of the sealing resin 30 with respect to the first region 451A. When viewed in the first direction z, the dimension D2 of the portion of the third conductive layer 43 overlapping the second region 451B in the second direction x is greater than the minimum dimension D1 of the first region 451A in the first direction z. Therefore, according to this configuration, in the semiconductor module B40, it is possible to reduce the parasitic inductance without increasing the power loss associated with the operation of each of the first circuit C1 and the second circuit C2. Further, in the semiconductor module B40, by providing a configuration common to the semiconductor module B10, the same operation and effects as those of the semiconductor module B10 are achieved.

### Fifth Embodiment

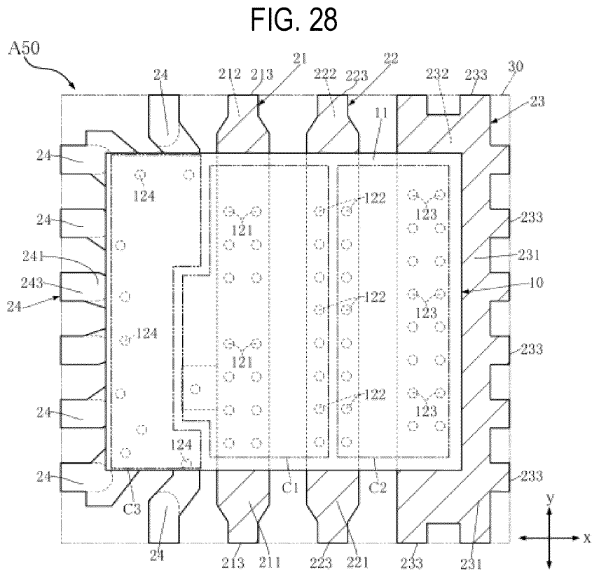

A semiconductor device A50 according to a fifth embodiment of the present disclosure will be described with reference to FIG. 28 to FIG. 32. In these figures, elements that are the same as or similar to those of the above-described semiconductor device A10 are denoted by the same reference numerals, and redundant descriptions thereof will be omitted. Here, for ease of understanding, FIG. 28 shows the sealing resin 30 in a transparent manner. In FIG. 28, the transparent sealing resin 30 is shown by an imaginary line.

The semiconductor device A50 includes a semiconductor element 10, a first terminal 21, a second terminal 22, a third terminal 23, a plurality of fourth terminals 24, and a sealing resin 30. In the semiconductor device A50, configurations of the semiconductor element 10, the first terminal 21, the second terminal 22, and the third terminal 23 are different from those of the semiconductor device A10.

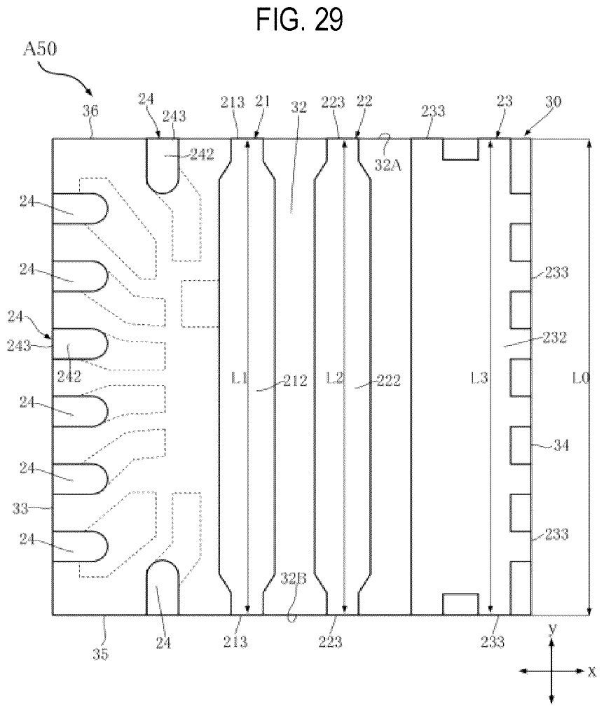

As shown in FIG. 28 and FIG. 29, the third mounting surface 232 of the third terminal 23 is located on the opposite side of the first mounting surface 212 of the first terminal 21 in the second direction x with respect to the second mounting surface 222 of the second terminal 22.

As shown in FIG. 29, the first mounting surface 212 of the first terminal 21 extends from the third edge 32A to the fourth edge 32B of the bottom surface 32 of the sealing resin 30. As a result, the dimension L1 of the first mounting surface 212 in the third direction y is equal to the dimension L0 of the sealing resin 30 in the third direction y. Therefore, the dimension L1 is 40% or more of the dimension L0. As shown in FIG. 28, when viewed in the first direction z, the first mounting surface 212 overlaps the first circuit C1 of the semiconductor element 10.

As shown in FIG. 29, the second mounting surface 222 of the second terminal 22 extends from the third edge 32A to the fourth edge 32B of the bottom surface 32 of the sealing resin 30. As a result, the dimension L2 of the second mounting surface 222 in the third direction y is equal to the dimension L0 of the sealing resin 30 in the third direction y. Therefore, the dimension L2 is 40% or more of the dimension L0. As shown in FIG. 28, when viewed in the first direction z, the second mounting surface 222 overlaps at least one selected from the group of the first circuit C1 and the second circuit C2 of the semiconductor element 10.

As shown in FIG. 29, the third mounting surface 232 of the third terminal 23 extends from the third edge 32A to the fourth edge 32B of the bottom surface 32 of the sealing resin 30. As a result, the dimension L3 of the third mounting surface 232 in the third direction y is equal to the dimension L0 of the sealing resin 30 in the third direction y. As shown in FIG. 28, when viewed in the first direction z, the third mounting surface 232 overlaps the second circuit C2 of the semiconductor element 10.

As shown in FIG. 28, in the semiconductor element 10, each of the plurality of second electrodes 122 overlaps either the first circuit C1 or the second circuit C2. In the semiconductor element 10, each of the plurality of third electrodes 123 overlaps the second circuit C2.

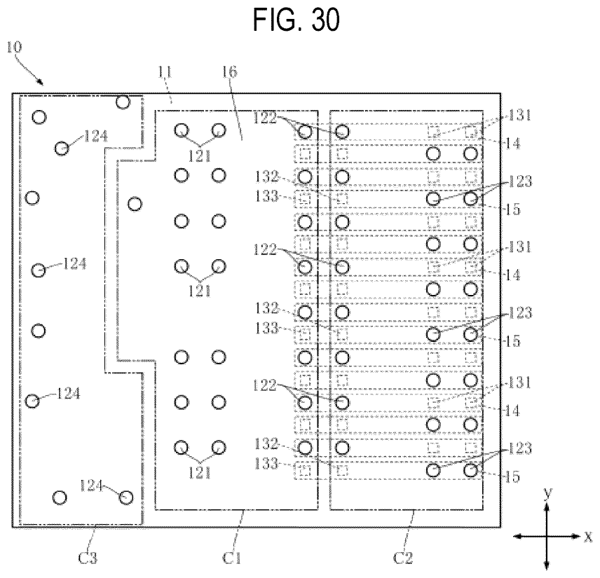

As shown in FIG. 30 to FIG. 32, the semiconductor element 10 includes a plurality of first pads 131, a plurality of second pads 132, a plurality of third pads 133, a plurality of first rewirings 14, a plurality of second rewirings 15, and a protective film 16.

As shown in FIG. 30, when viewed in the first direction z, each of the plurality of first pads 131 overlaps the second circuit C2. Each of the plurality of first pads 131 is electrically connected to the second circuit C2. When viewed in the first direction z, each of the plurality of second pads 132 overlaps the second circuit C2. Each of the plurality of second pads 132 is electrically connected to the second circuit C2. When viewed in the first direction z, each of the plurality of third pads 133 overlaps the first circuit C1. Each of the plurality of third pads 133 is electrically connected to the first circuit C1.

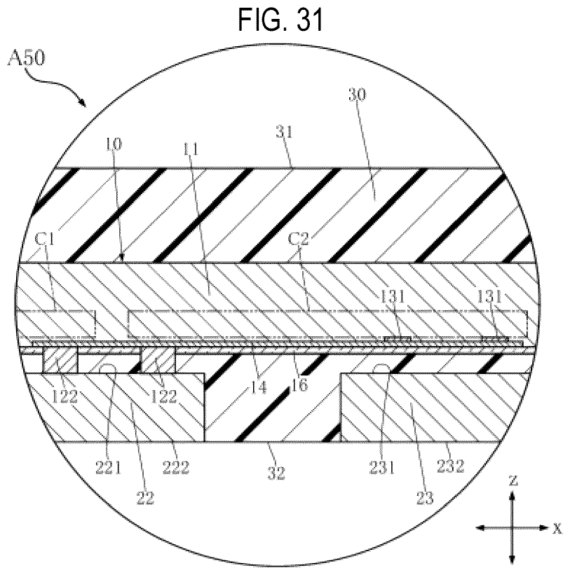

As shown in FIG. 30 and FIG. 31, each of the plurality of first rewirings 14 electrically connects two of the plurality of first pads 131 and two of the plurality of second electrodes 122. Each of the plurality of first rewirings 14 extends in the second direction x. When viewed in the first direction z, each of the plurality of first rewirings 14 overlaps each of the first circuit C1 and the second circuit C2.

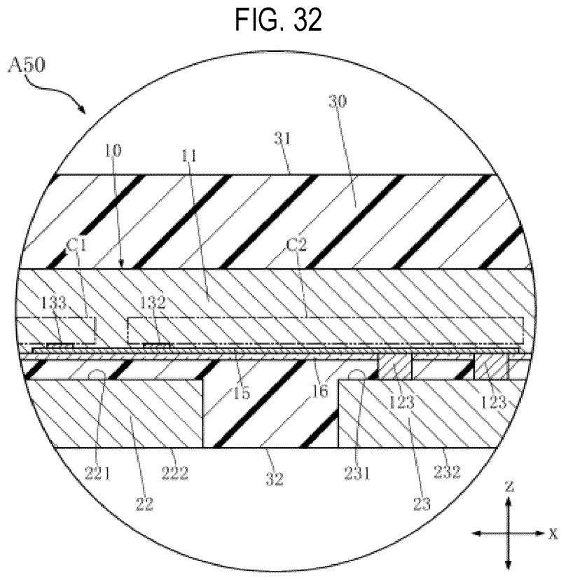

As shown in FIG. 30 and FIG. 32, each of the plurality of second rewirings 15 electrically connects one of the plurality of second pads 132, one of the plurality of third pads 133, and two of the plurality of third electrodes 123. Each of the plurality of second rewirings 15 extends in the second direction x. When viewed in the first direction z, each of the plurality of second rewirings 15 overlaps each of the first circuit C1 and the second circuit C2.

As shown in FIG. 30 to FIG. 32, the protective film 16 covers one side of the main body 11 in the first direction z, the plurality of first rewirings 14, and the plurality of second rewirings 15. The protective film 16 is an insulator. The protective film 16 is made of a material containing, for example, polyimide. Each of the plurality of first electrodes 121, the plurality of second electrodes 122, the plurality of third electrodes 123, and the plurality of fourth electrodes 124 protrudes from the protective film 16 in the first direction z.

Next, operation and effects of the semiconductor device A50 will be described.

The semiconductor device A50 includes the first terminal 21, the second terminal 22, the third terminal 23, the semiconductor element 10, and the sealing resin 30. The semiconductor element 10 includes the first circuit C1 and the second circuit C2. The third mounting surface 232 of the third terminal 23 is located on the opposite side of the first mounting surface 212 of the first terminal 21 in the second direction x with respect to the second mounting surface 222 of the second terminal 22. The dimensions L1 and L2 of the first mounting surface 212 and the second mounting surface 222 in the third direction y are 40% or more of the dimension L0 of the sealing resin 30 in the third direction y. By adopting this configuration, the conductive path from the first terminal 21 to the second terminal 22 via the first circuit C1 and the second circuit C2 in this order is further shortened. As a result, in the semiconductor device A50, the parasitic inductance caused by the conductive path is further reduced. Therefore, according to this configuration, in the semiconductor device A50, it is possible to reduce the parasitic inductance without increasing the power loss associated with the operation of each of the first circuit C1 and the second circuit C2.

The semiconductor device A50 includes the first terminal 21, the second terminal 22, the third terminal 23, the semiconductor element 10, and the sealing resin 30. The semiconductor element 10 includes the first circuit C1 and the second circuit C2. The third mounting surface 232 of the third terminal 23 is located on the opposite side of the first mounting surface 212 of the first terminal 21 in the second direction x with respect to the second mounting surface 222 of the second terminal 22. When viewed in the first direction z, the first mounting surface 212 and the third mounting surface 232 overlap the first circuit C1 and the second circuit C2, respectively. When viewed in the first direction z, the second mounting surface 222 overlaps at least one selected from the group of the first circuit C1 and the second circuit C2. By employing this configuration, the conductive path from the first terminal 21 to the second terminal 22 via the first circuit C1 and the second circuit C2 in this order is further shortened. As a result, in the semiconductor device A50, the parasitic inductance caused by the conductive path is further reduced. Therefore, according to this configuration, in the semiconductor device A50, it is possible to reduce the parasitic inductance without increasing the power loss associated with the operation of each of the first circuit C1 and the second circuit C2.

In the semiconductor device A50, even in a case where a position of the first terminal 21 and a position of the second terminal 22 are interchanged, the above-described operation and effects are achieved.

The present disclosure is not limited to the above-described embodiments. The specific configuration of each part of the present disclosure can be freely designed in various ways.

The semiconductor modules B10 to B40 and the semiconductor device A50 in the present disclosure are intended to be applied to step-down DC/DC converters. In addition, the semiconductor modules B10 to B40 and the semiconductor device A50 in the present disclosure can be applied to step-up or inverting converters, and switching applications other than converters.

The present disclosure includes embodiments described in the supplementary notes set forth below.

### [Supplementary Note 1]

A semiconductor module (B10) including:
a substrate (40); and
a semiconductor device (A10) that is located on one side of the substrate in a first direction (z) and is conductively bonded to the substrate,
wherein the semiconductor device includes:
a first terminal (21), a second terminal (22), and a third terminal (23);
a semiconductor element (10) that is located on one side of the first terminal, the second terminal, and the third terminal in the first direction; and
a sealing resin (30) that covers the semiconductor element,
wherein the semiconductor element includes a first circuit (C1) and a second circuit (C2) that are connected in series with each other,
wherein the first circuit is electrically connected to the first terminal and the third terminal,
wherein the second circuit is electrically connected to the second terminal and the third terminal,
wherein the sealing resin has a bottom surface (32) facing the substrate,
wherein the first terminal, the second terminal, and the third terminal have a first mounting surface (212), a second mounting surface (222), and a third mounting surface (232), respectively, which are exposed from the bottom surface,
wherein the second mounting surface is spaced apart from the first mounting surface in a second direction (x) perpendicular to the first direction,
wherein the first mounting surface includes a first edge (212A) that extends in a third direction (y) perpendicular to the first direction and the second direction,
wherein the second mounting surface includes a second edge (222A) that extends in the third direction and is located adjacent to the first edge in the second direction,
wherein the third mounting surface is located between the first edge and an extension line of the first edge, and the second edge and an extension line of the second edge,
wherein the bottom surface includes a third edge (32A) that extends in the second direction and is spaced apart from the third mounting surface,
wherein the substrate includes:
an insulating layer (45) having a mounting surface (451) facing the bottom surface; and
a first conductive layer (41), a second conductive layer (42), and a third conductive layer (43), each of which is mounted on the mounting surface,
wherein the first mounting surface, the second mounting surface and the third mounting surface are conductively bonded to the first conductive layer, the second conductive layer, and the third conductive layer, respectively,
wherein the mounting surface includes a first region (451A) and a second region (451B), each of which entirely overlaps the bottom surface when viewed in the first direction,
wherein the first region is interposed between the first conductive layer and the second conductive layer when viewed in the first direction,
wherein the second region is located on an opposite side of the third edge with respect to the first region when viewed in the first direction, and
wherein a dimension (D2) of a portion of the third conductive layer overlapping the second region in the second direction when viewed in the first direction is greater than a minimum dimension (D1) of the first region in the second direction.

### [Supplementary Note 2]

The semiconductor module (B10) of Supplementary Note 1, wherein the semiconductor element (10) includes a first electrode (121) electrically connected to the first circuit (C1), a second electrode (122) electrically connected to the second circuit (C2), and a third electrode (123) electrically connected to the first circuit and the second circuit, and
wherein the first electrode, the second electrode, and the third electrode are conductively bonded to the first terminal, the second terminal, and the third terminal, respectively.

### [Supplementary Note 3]

The semiconductor module (B10) of Supplementary Note 2, wherein the third mounting surface (232) is located on an opposite side of a side on which the third edge (32A) is located, with respect to the first mounting surface (212) and the second mounting surface (222) in the third direction (y).

### [Supplementary Note 4]

The semiconductor module (B10) of Supplementary Note 3, wherein a predetermined gap is provided between the third mounting surface (232) and each of the first mounting surface (212) and the second mounting surface (222) in the third direction.

### [Supplementary Note 5]

The semiconductor module (B10) of Supplementary Note 4, wherein a dimension (L1, L2) of each of the first mounting surface (212) and the second mounting surface (222) in the third direction (y) is 40% or more of a dimension (L0) of the sealing resin (30) in the third direction.

### [Supplementary Note 6]

The semiconductor module (B10) of Supplementary Note 3, wherein the first mounting surface (212) and the second mounting surface (222) overlap the first circuit (C1) and the second circuit (C2), respectively, when viewed in the first direction (z).

### [Supplementary Note 7]

The semiconductor module (B10) of Supplementary Note 6, wherein the third terminal (23) includes a first portion (23A) including the third mounting surface (232) and a second portion (23B) that is connected to the first portion and is covered with the sealing resin (30),
wherein a dimension of the second portion in the first direction (z) is smaller than a dimension of the first portion in the first direction, and
wherein the third electrode (123) is conductively bonded to the second portion.

### [Supplementary Note 8]

The semiconductor module (B10) of Supplementary Note 7, wherein the bottom surface (32) includes a fourth edge (32B) that extends in the second direction (x) and is located on an opposite side of the third edge (32A) with respect to the first mounting surface (212) and the second mounting surface (222), and
wherein the third mounting surface (232) reaches the fourth edge.

### [Supplementary Note 9]

The semiconductor module (B10) of Supplementary Note 8, wherein each of the first mounting surface (212) and the second mounting surface (222) reaches the third edge (32A).

### [Supplementary Note 10]

The semiconductor module (B20) of Supplementary Note 9, wherein the third mounting surface (232) is spaced apart from each of the first circuit (C1) and the second circuit (C2) when viewed in the first direction (z).

### [Supplementary Note 11]

The semiconductor module (B10) of Supplementary Note 9, wherein the third mounting surface (232) overlaps at least one selected from the group of the first circuit (C1) and the second circuit (C2) when viewed in the first direction (z).

### [Supplementary Note 12]

The semiconductor module (B30) of Supplementary Note 8, wherein the first mounting surface (212) includes a first surface (212B) and a second surface (212C), which are spaced apart from each other in the third direction (y).

### [Supplementary Note 13]

The semiconductor module (B10) of any one of Supplementary Notes 6 to 12, further including a fourth terminal (24),
wherein the semiconductor element (10) includes a third circuit (C3) that is electrically connected to each of the first circuit (C1) and the second circuit (C2),
wherein the fourth terminal is electrically connected to the third circuit,
wherein the fourth terminal has a fourth mounting surface (242) that is exposed from the bottom surface (320, and
wherein a dimension of each of the first mounting surface (212) and the second mounting surface (222) in the third direction (y) is greater than a dimension of the fourth mounting surface in each of the second direction (x) and the third direction.

### [Supplementary Note 14]

The semiconductor module (B10) of Supplementary Note 13, wherein the fourth terminal (24) is located on the opposite side of the third terminal (23) with respect to the first terminal (21) in the second direction (x).

### [Supplementary Note 15]

The semiconductor module (B10) of Supplementary Note 14, further including an input capacitor (50) that is conductively bonded to the first conductive layer (41) and the second conductive layer (42),
wherein the input capacitor is located on an opposite side of the first mounting surface (212) and the second mounting surface (222) with respect to the third edge (32A) in the third direction (y).

### [Supplementary Note 16]

A semiconductor device (A50) including:
a first terminal (21), a second terminal (22), and a third terminal (23);
a semiconductor element (10) that is located on one side of the first terminal, the second terminal, and the third terminal in a first direction (z); and
a sealing resin (30) that covers the semiconductor element,
wherein the semiconductor element includes a first circuit (C1) and a second circuit (C2) that are connected in series with each other,
wherein the first circuit is electrically connected to the first terminal and the third terminal,
wherein the second circuit is electrically connected to the second terminal and the third terminal,
wherein the sealing resin has a bottom surface (32) facing the other side in the first direction,
wherein the first terminal, the second terminal, and the third terminal have a first mounting surface (212), a second mounting surface (222), and a third mounting surface (232), respectively, which are exposed from the bottom surface,
wherein the third mounting surface is located on an opposite side of the first mounting surface with respect to the second mounting surface in a second direction (x) perpendicular to the first direction, and
wherein a dimension of each of the first mounting surface and the second mounting surface is 40% or more of a dimension of the sealing resin in a third direction (y) perpendicular to each of the first direction and the second direction.

### [Supplementary Note 17]

A semiconductor device (A50) including:
a first terminal (21), a second terminal (22), and a third terminal (23);
a semiconductor element (10) that is located on one side of the first terminal, the second terminal, and the third terminal in a first direction (z); and
a sealing resin (30) that covers the semiconductor element,
wherein the semiconductor element includes a first circuit (C1) and a second circuit (C2) that are connected in series with each other,
wherein the first circuit is electrically connected to the first terminal and the third terminal,
wherein the second circuit is electrically connected to the second terminal and the third terminal,
wherein the sealing resin has a bottom surface (32) facing the other side in the first direction,
wherein the first terminal, the second terminal, and the third terminal have a first mounting surface (212), a second mounting surface (222), and a third mounting surface (232), respectively, which are exposed from the bottom surface,
wherein the third mounting surface is located on an opposite side of the first mounting surface with respect to the second mounting surface in a second direction (x) perpendicular to the first direction,
wherein the first mounting surface and the third mounting surface overlap the first circuit and the second circuit, respectively, when viewed in the first direction, and
wherein the second mounting surface overlaps at least one selected from the group of the first circuit and the second circuit when viewed in the first direction.

### [Supplementary Note 18]

The semiconductor device (A50) of Supplementary Note 16 or 17, wherein the semiconductor element (10) includes a first electrode (121) electrically connected to the first circuit (C1), a second electrode (122) electrically connected to the second circuit (C2), and a third electrode (123) electrically connected to the first circuit and the second circuit, and
wherein the first electrode, the second electrode, and the third electrode are conductively bonded to the first terminal (21), the second terminal (22), and the third terminal (23), respectively.

### [Supplementary Note 19]

The semiconductor device (A50) of Supplementary Note 18, wherein the semiconductor element (10) includes a first pad (131) electrically connected to the second circuit (C2), and a first rewiring (14) that electrically connects the first pad and the second electrode (122), and
wherein the first rewiring overlaps each of the first circuit (C1) and the second circuit when viewed in the first direction (z).

### [Supplementary Note 20]

The semiconductor device (A50) of Supplementary Note 19, wherein the semiconductor element (10) includes a second pad (132) electrically connected to the first circuit (C1), and a second rewiring (15) that electrically connects the second pad and the third electrode (123), and
wherein the second rewiring (15) overlaps each of the first circuit and the second circuit (C2) when viewed in the first direction (z).

### [Supplementary Note 21]

The semiconductor module (B10) of Supplementary Note 9, wherein an entirety of each of the first mounting surface (212) and the second mounting surface (222) is located between the third edge (32A) and the second region (451B) in the third direction (y).

### [Supplementary Note 22]

The semiconductor module (B40) of Supplementary Note 11, wherein each of the first mounting surface (212) and the second mounting surface (222) reaches the fourth edge (32B).

### [Supplementary Note 23]

The semiconductor module (B30) of Supplementary Note 12, wherein the second mounting surface (222) includes a third surface (222B) and a fourth surface (222C) that are spaced apart from each other in the third direction (y).

### [Supplementary Note 24]

The semiconductor device (A50) of Supplementary Note 20, further including a fourth terminal (24),
wherein the semiconductor element (10) includes a third circuit (C3) that is electrically connected to each of the first circuit (C1) and the second circuit (C2),
wherein the fourth terminal is electrically connected to the third circuit,
wherein the fourth terminal has a fourth mounting surface (242) exposed from the bottom surface (32), and
wherein a dimension of each of the first mounting surface (212) and the second mounting surface (222) in the third direction (y) is greater than a dimension of the fourth mounting surface in each of the second direction (x) and the third direction (y).

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor module comprising:
a substrate; and
a semiconductor device that is located on one side of the substrate in a first direction and is conductively bonded to the substrate,
wherein the semiconductor device includes:
a first terminal, a second terminal, and a third terminal;
a semiconductor element that is located on one side of the first terminal, the second terminal, and the third terminal in the first direction; and
a sealing resin that covers the semiconductor element,
wherein the semiconductor element includes a first circuit and a second circuit that are connected in series with each other,
wherein the first circuit is electrically connected to the first terminal and the third terminal,
wherein the second circuit is electrically connected to the second terminal and the third terminal,
wherein the sealing resin has a bottom surface facing the substrate,
wherein the first terminal, the second terminal, and the third terminal have a first mounting surface, a second mounting surface, and a third mounting surface, respectively, which are exposed from the bottom surface,
wherein the second mounting surface is spaced apart from the first mounting surface in a second direction perpendicular to the first direction,
wherein the first mounting surface includes a first edge that extends in a third direction perpendicular to the first direction and the second direction,
wherein the second mounting surface includes a second edge that extends in the third direction and is located adjacent to the first edge in the second direction,
wherein the third mounting surface is located between the first edge and an extension line of the first edge, and the second edge and an extension line of the second edge,
wherein the bottom surface includes a third edge that extends in the second direction and is spaced apart from the third mounting surface,
wherein the substrate includes:
an insulating layer having a mounting surface facing the bottom surface; and
a first conductive layer, a second conductive layer, and a third conductive layer, each of which is mounted on the mounting surface,
wherein the first mounting surface, the second mounting surface, and the third mounting surface are conductively bonded to the first conductive layer, the second conductive layer, and the third conductive layer, respectively,
wherein the mounting surface includes a first region and a second region, each of which entirely overlaps the bottom surface when viewed in the first direction,
wherein the first region is interposed between the first conductive layer and the second conductive layer when viewed in the first direction,
wherein the second region is located on an opposite side of the third edge with respect to the first region when viewed in the first direction, and
wherein a dimension of a portion of the third conductive layer overlapping the second region in the second direction when viewed in the first direction is greater than a minimum dimension of the first region in the second direction.

2. The semiconductor module of claim 1, wherein the semiconductor element includes a first electrode electrically connected to the first circuit, a second electrode electrically connected to the second circuit, and a third electrode electrically connected to the first circuit and the second circuit, and
wherein the first electrode, the second electrode, and the third electrode are conductively bonded to the first terminal, the second terminal, and the third terminal, respectively.

3. The semiconductor module of claim 2, wherein the third mounting surface is located on an opposite side of a side on which the third edge is located, with respect to the first mounting surface and the second mounting surface in the third direction.

4. The semiconductor module of claim 3, wherein a predetermined gap is provided between the third mounting surface and each of the first mounting surface and the second mounting surface in the third direction.

5. The semiconductor module of claim 4, wherein a dimension of each of the first mounting surface and the second mounting surface in the third direction is 40% or more of a dimension of the sealing resin in the third direction.

6. The semiconductor module of claim 3, wherein the first mounting surface and the second mounting surface overlap the first circuit and the second circuit, respectively, when viewed in the first direction.

7. The semiconductor module of claim 6, wherein the third terminal includes a first portion including the third mounting surface and a second portion that is connected to the first portion and is covered with the sealing resin,
wherein a dimension of the second portion in the first direction is smaller than a dimension of the first portion in the first direction, and
wherein the third electrode is conductively bonded to the second portion.

8. The semiconductor module of claim 7, wherein the bottom surface includes a fourth edge that extends in the second direction and is located on an opposite side of the third edge with respect to the first mounting surface and the second mounting surface, and
wherein the third mounting surface reaches the fourth edge.

9. The semiconductor module of claim 8, wherein each of the first mounting surface and the second mounting surface reaches the third edge.

10. The semiconductor module of claim 9, wherein the third mounting surface is spaced apart from each of the first circuit and the second circuit when viewed in the first direction.

11. The semiconductor module of claim 9, wherein the third mounting surface overlaps at least one selected from the group of the first circuit and the second circuit when viewed in the first direction.

12. The semiconductor module of claim 8, wherein the first mounting surface includes a first surface and a second surface, which are spaced apart from each other in the third direction.

13. The semiconductor module of claim 6, further comprising a fourth terminal,
wherein the semiconductor element includes a third circuit that is electrically connected to each of the first circuit and the second circuit,
wherein the fourth terminal is electrically connected to the third circuit,
wherein the fourth terminal has a fourth mounting surface that is exposed from the bottom surface, and
wherein a dimension of each of the first mounting surface and the second mounting surface in the third direction is greater than a dimension of the fourth mounting surface in each of the second direction and the third direction.

14. The semiconductor module of claim 13, wherein the fourth terminal is located on an opposite side of the third terminal with respect to the first terminal in the second direction.

15. The semiconductor module of claim 14, further comprising an input capacitor that is conductively bonded to the first conductive layer and the second conductive layer,
wherein the input capacitor is located on an opposite side of the first mounting surface and the second mounting surface with respect to the third edge in the third direction.

16. A semiconductor device comprising:
a first terminal, a second terminal, and a third terminal;
a semiconductor element that is located on one side of the first terminal, the second terminal, and the third terminal in a first direction; and
a sealing resin that covers the semiconductor element,
wherein the semiconductor element includes a first circuit and a second circuit that are connected in series with each other,
wherein the first circuit is electrically connected to the first terminal and the third terminal,
wherein the second circuit is electrically connected to the second terminal and the third terminal,
wherein the sealing resin has a bottom surface facing the other side in the first direction,
wherein the first terminal, the second terminal, and the third terminal have a first mounting surface, a second mounting surface, and a third mounting surface, respectively, which are exposed from the bottom surface,
wherein the third mounting surface is located on an opposite side of the first mounting surface with respect to the second mounting surface in a second direction perpendicular to the first direction, and
wherein a dimension of each of the first mounting surface and the second mounting surface is 40% or more of a dimension of the sealing resin in a third direction perpendicular to each of the first direction and the second direction.

17. A semiconductor device comprising:
a first terminal, a second terminal, and a third terminal;
a semiconductor element that is located on one side of the first terminal, the second terminal, and the third terminal in a first direction; and
a sealing resin that covers the semiconductor element,
wherein the semiconductor element includes a first circuit and a second circuit that are connected in series with each other,
wherein the first circuit is electrically connected to the first terminal and the third terminal,
wherein the second circuit is electrically connected to the second terminal and the third terminal,
wherein the sealing resin has a bottom surface facing the other side in the first direction,
wherein the first terminal, the second terminal, and the third terminal have a first mounting surface, a second mounting surface, and a third mounting surface, respectively, which are exposed from the bottom surface,
wherein the third mounting surface is located on an opposite side of the first mounting surface with respect to the second mounting surface in a second direction perpendicular to the first direction,
wherein the first mounting surface and the third mounting surface overlap the first circuit and the second circuit, respectively, when viewed in the first direction, and
wherein the second mounting surface overlaps at least one selected from the group of the first circuit and the second circuit when viewed in the first direction.

18. The semiconductor device of claim 16, wherein the semiconductor element includes a first electrode electrically connected to the first circuit, a second electrode electrically connected to the second circuit, and a third electrode electrically connected to the first circuit and the second circuit, and
wherein the first electrode, the second electrode, and the third electrode are conductively bonded to the first terminal, the second terminal, and the third terminal, respectively.

19. The semiconductor device of claim 18, wherein the semiconductor element includes a first pad electrically connected to the second circuit, and a first rewiring that electrically connects the first pad and the second electrode, and
wherein the first rewiring overlaps each of the first circuit and the second circuit when viewed in the first direction.

20. The semiconductor device of claim 19, wherein the semiconductor element includes a second pad electrically connected to the first circuit, and a second rewiring that electrically connects the second pad and the third electrode, and
wherein the second rewiring overlaps each of the first circuit and the second circuit when viewed in the first direction.
